(19) United States
(12) Patent Application Publication
(10) Pub. No.: US 2005/0245059 A1
(43) Pub. Date: Nov. 3, 2005

(54) Method for making an interconnect pad

(76) Inventors: Yuan Yuan, Austin, TX (US); Burton J. Carpenter, Austin, TX (US); Rung-Kuang Lo, Austin, TX (US); Joachim C. Rayos, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/836,152

(22) Filed: Apr. 30, 2004

(51) Int. Cl. H01L 21/44

(52) U.S. Cl. 438/612

(57) ABSTRACT

An interconnect pad is made to have a convex shape which is a shape that has been found to useful in improving the reliability of solder joints. A seed pillar is formed by plating over a metal layer. This seed pillar is smaller than the intended size of the interconnect pad. After formation of this small seed pillar, a plating step is performed over the pillar that forms the desired convex shape for the interconnect pad.

### RELATED PATENT APPLICATIONS

This application is related to U.S. application Ser. No. 10/306,626, filed Nov. 27, 2002, entitled “Improving Solder Joint Reliability By Changing Solder Pad Surface From Flat to Convex Shape,” and assigned to the assignee hereof.

### FIELD OF THE INVENTION

The present invention relates generally to solder joints, and more particularly to methods for making interconnect pads which can be used to improve the integrity of solder joints.

### RELATED ART

Solder joints are used widely throughout the semiconductor art as a convenient means for forming physical and/or electrical connections between device components. Such components may be, for example, a die and a packaging substrate, or a packaging substrate and a Printed Circuit Board (PCB). Typically, solder joint formation involves the mechanical or electrochemical deposition of solder onto a surface of at least one of the components to be joined together, followed by solder reflow. In either case the connection includes a interconnect pad on each surface and solder attached to the two interconnect pads. When the two components expand at different rates because of different coefficients of thermal expansion, a shear stress is applied to the joint between the solder and the two interconnect pads. This stress can cause a fracture at the joint and thus a failure.

Thus, there is a need for structures that overcome this and other potential problems and methods for obtaining such structures.

### BRIEF DESCRIPTION OF THE DRAWINGS

The present invention is illustrated by way of example and not limited by the accompanying figures, in which like references indicate similar elements, and in which:

FIG. 1 is a cross section of a solder interface structure in a stage in processing according to a first embodiment of the invention;

FIG. 2 is a cross section of the solder interface structure of FIG. 1 in a stage in a subsequent processing according to the first embodiment of the invention;

FIG. 3 is a cross section of the solder interface structure of FIG. 2 in a subsequent stage in processing according to the first embodiment of the invention;

FIG. 4 is a cross section of the solder interface structure of FIG. 3 in a subsequent stage in processing according to the first embodiment of the invention;

FIG. 5 is a cross section of the solder interface structure of FIG. 4 in a subsequent stage in processing according to the first embodiment of the invention;

FIG. 6 is a cross section of the v structure of FIG. 5 in a subsequent stage in processing according to the first embodiment of the invention;

FIG. 7 is a cross section of the solder interface structure of FIG. 6 in a subsequent stage in processing according to the first embodiment of the invention;

FIG. 8 is a cross section of the solder interface structure of FIG. 7 in a subsequent stage in processing according to the first embodiment of the invention;

FIG. 9 is a cross section of a solder interface structure in a stage in processing according to a second embodiment of the invention;

FIG. 10 is a cross section of the solder interface structure of FIG. 9 in a subsequent stage in processing according to the second embodiment of the invention;

FIG. 11 is a cross section of the v structure of FIG. 10 in a subsequent stage in processing according to the second embodiment of the invention;

FIG. 12 is a cross section of the solder interface structure of FIG. 11 in a subsequent stage in processing according to the second embodiment of the invention;

FIG. 13 is a cross section of the solder interface structure of FIG. 12 in a subsequent stage in processing according to the second embodiment of the invention;

FIG. 14 is a cross section of the solder interface structure of FIG. 13 in a subsequent stage in processing according to the second embodiment of the invention; and

FIG. 15 is a cross section of the solder interface structure of FIG. 14 in a subsequent stage in processing according to the second embodiment of the invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

In one aspect an interconnect pad is made to have a convex shape, which is a shape that has been found to be useful in improving the reliability of solder joints. A seed pillar is formed by plating over a metal layer. This seed pillar is smaller than the intended size of the interconnect pad. After formation of this small seed pillar, a regular plating step is performed over the seed pillar that forms the desired convex shape. This is better understood by reference to the figures and the following description.

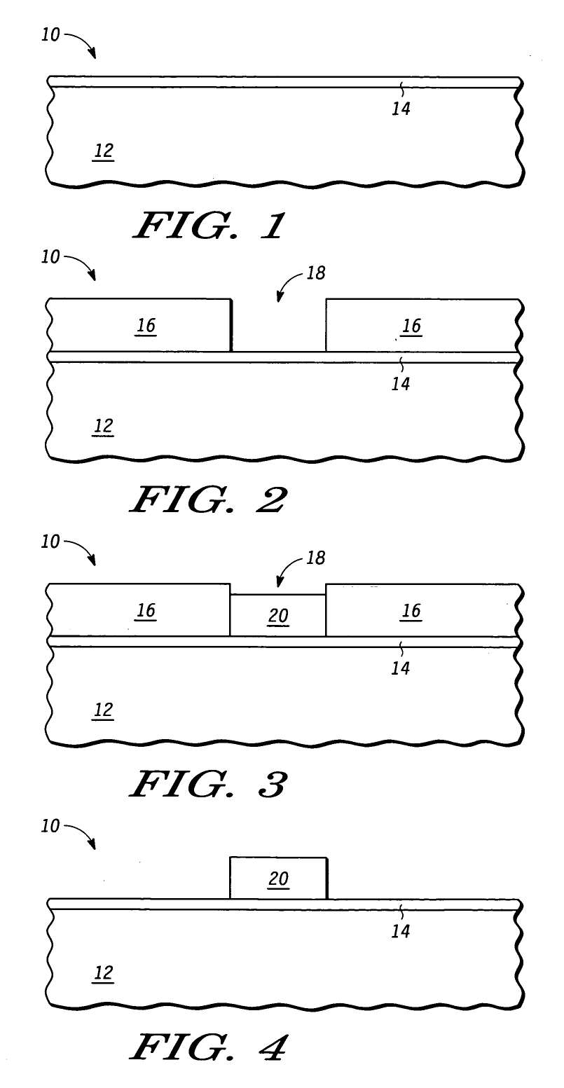

Shown in FIG. 1 is a solder interface structure 10 having a substrate 12 and a seed layer 14 over the substrate 12. Substrate 12 is preferably an integrated circuit but may alternatively be an integrated circuit packaging material such as a ceramic or organic substrate. It may also be the material used in end products for housing and routing. This, for example, is typically a PCB (printed circuit board). Seed layer 14 is preferably copper at a thickness of about 0.5 micron. Substrate 12, as an integrated circuit, will typically make electrical contact to seed layer 14 by way of vias under seed layer 14. Other thicknesses and materials may be useful as a seed layer also.

Shown in FIG. 2 is solder interface structure 10 after formation of a photoresist layer 16 that is patterned to have hole 18 therein. This hole width is dependent on the application. In this example, which is for use on an integrated circuit, the width of hole 18 is preferably about 50 microns for a pad that is intended to have an overall width of 100 microns. The hole width will vary with different pad widths. For use on packaging material it would be bigger and for PCB probably even bigger.

Shown in FIG. 3 is solder interface structure 10 after forming a seed pillar 20 in hole 18. Seed pillar 20 is formed of copper by electroplating, which may be either electrolytic or electroless. The height is about 25 microns high. Other materials may also be deposited to form pillar 20. The pillar height may be shorter than the height of the photoresist layer 16 as shown in the drawing or alternatively taller than the height of the photoresist layer. The top surface of pillar may not necessarily be flat. It may be convex, mushroom-shaped, or some other shape depending on the processing parameters and the control thereof.

Shown in FIG. 4 is solder interface structure 10 after removal of photoresist 16 leaving seed pillar 20.

Shown in FIG. 5 is solder interface structure 10 after forming and patterning photoresist to result in a photoresist layer 22 that varies for different pad sizes. It surrounds and is spaced from pillar 20 by about 25 microns. This dimension varies for different pad sizes and will be bigger for the packaging material and PCB cases.

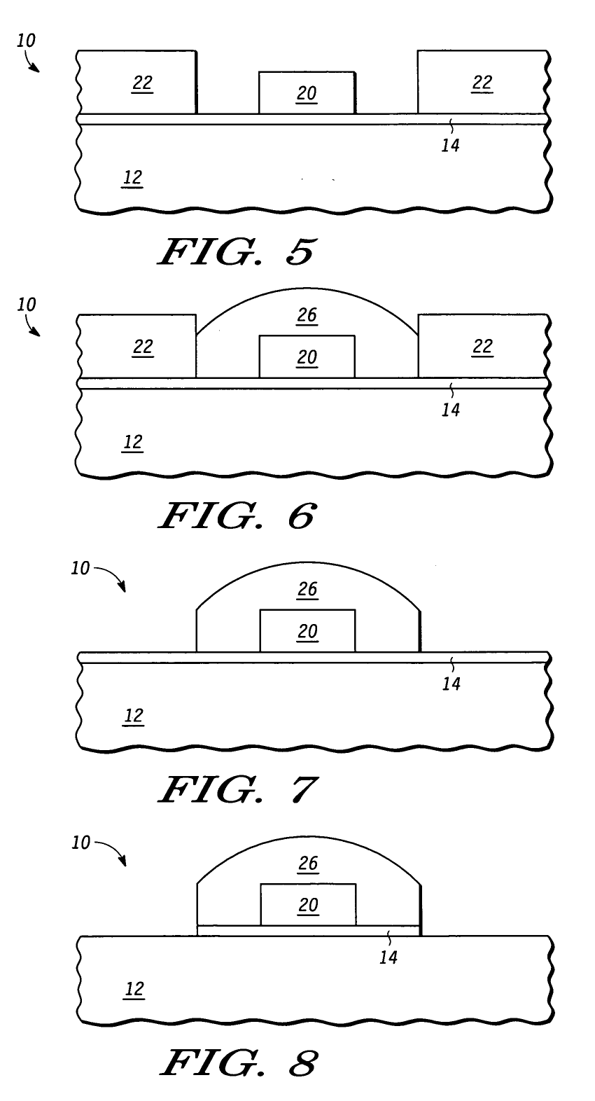

Shown in FIG. 6 is solder interface structure 10 after forming a conductive layer 26 over pillar 20 and the exposed portion of seed layer 14. This conductive layer 26 functions as a interconnect pad and has a convex shape. This could also be called dome-shaped. Conductive layer 26 is preferably copper formed by plating. Other materials may also be effective for this. The peak height of conductive layer 26 is about 50 microns. Also conductive traces could be formed at this stage.

Shown in FIG. 7 is solder interface structure 10 after removal of photoresist layer 22. This results in exposing the portion of seed layer 14 in the area where photoresist 22 was just removed.

Shown in FIG. 8 is solder interface structure 10 after an etch step that removes the exposed portion of seed layer 14. This can be done without a mask because seed layer 14 is very thin compared to the height of conductive layer 26. The height of conductive layer 26 is only slightly reduced in this process.

FIG. 9 begins an alternative method to that described for FIGS. 1-8. Shown in FIG. 9 is a solder interface structure 30 having a substrate 32 and a seed layer 34, which has been patterned, over substrate 32. The area of seed layer 34 is for interconnecting traces as well as for forming an interconnect pad. Substrate 32, as for substrate 12, is preferably an integrated circuit but may be something else as in the manner of substrate 12. Seed layer 34 is a little thicker than seed layer 14 of FIG. 1 because of the additional processing that it undergoes compared to seed layer 14. It may also be thicker because it may operate as a trace layer as well. In this example of substrate 32 being an integrated circuit, this seed layer 34 is preferably in the range of 1-3 microns. In the case of a packaging material or PCB, the thickness would preferably be even thicker, for example, 30 microns. In those cases it would be a trace layer.

Shown in FIG. 10 is solder interface structure 30 after formation of a photoresist layer that is patterned to form photoresist layer 36 with a hole 38 like hole 18 shown in FIG. 2.

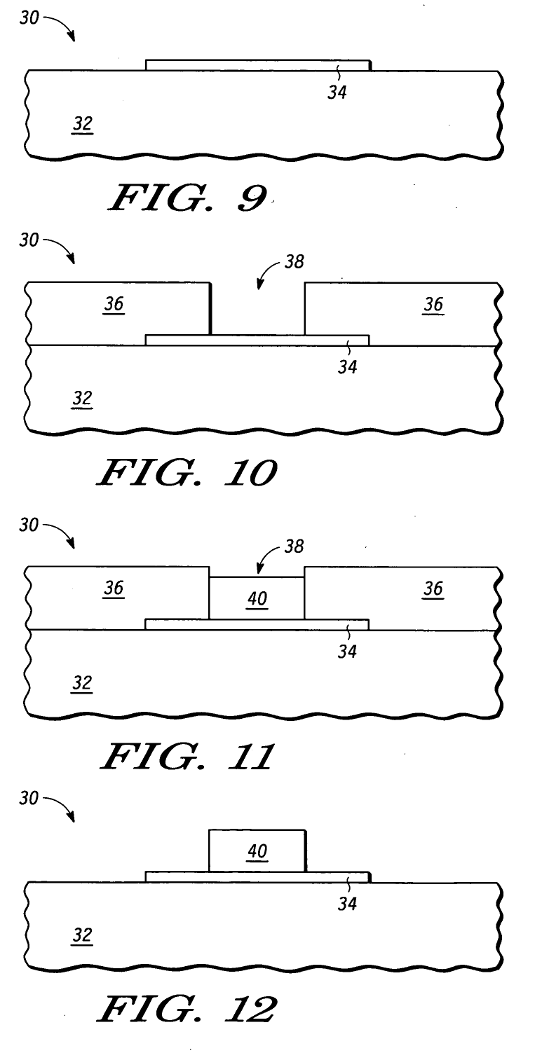

Shown in FIG. 11 is solder interface structure 30 after formation of a pillar 40 like pillar 20 of FIG. 3. As for the case in FIG. 3, the pillar height and shape may vary.

Shown in FIG. 12 is solder interface structure 30 after removing photoresist layer 36 which leaves seed layer 34 and exposes a portion of substrate 32. Pillar 40 is over seed layer 34.

Shown in FIG. 13 is solder interface structure 30 after applying a layer of photoresist and patterning it to form photoresist layer 42 that covers the exposed portion of substrate 32 and has an opening that exposes pillar 40 and portions of seed layer surrounding pillar 40.

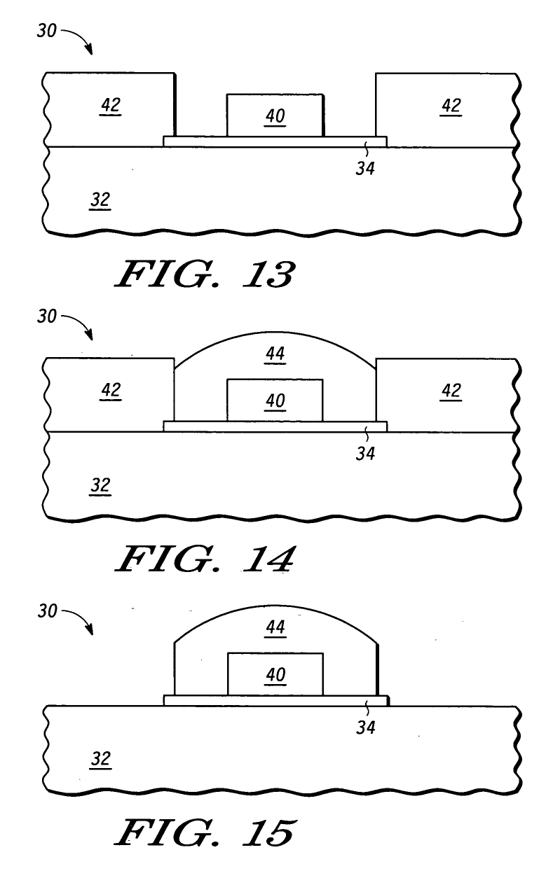

Shown in FIG. 14 is solder interface structure 30 after forming a conductive layer 44 by plating. Conductive layer 44 functions as an interconnect pad and has a convex shape, with characteristics similar to conductive layer 26 as described for FIG. 6.

Shown in FIG. 15 is solder interface structure 30 after removal of photoresist layer 42 and shows a completed interconnect pad 44.

The convex shape has been found to provide an effective solder joint. In situations where a solder joint has been found to be unreliable due to a shear force, this shape of interconnect pad has been found to improve reliability. This is explained in more detail in U.S. application Ser. No. 10/306,626, filed Nov. 27, 2002, and entitled “Improving Solder Joint Reliability By Changing Solder Pad Surface From Flat to Convex Shape,” which is incorporated herein by reference. In these described embodiments, the convex shape is deposited on a seed pillar that is metal. There may be cases, however, in which the convex shell could be deposited on a non-conductive seed pillar.

In the foregoing specification, the invention has been described with reference to specific embodiments. However, one of ordinary skill in the art appreciates that various modifications and changes can be made without departing from the scope of the present invention as set forth in the claims below. For example, other embodiments may relate to other substrates than an integrated circuit, and they may involve additional features such as conductive traces. Also the copper deposition technique has been described as being plating and there may be another way to achieve this deposition in an effective way. Further, the plating technique used may be either electroless or electrolytic. Whereas photoresist layers have been used in the described processing, photoimaged or laser defined resist could be used. Also the interconnect pad was explained as being useful for solder, but it may also be useful for another type of conductive connection. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method for forming a convex solder interconnect pad, comprising:
creating a seed pillar over a first substrate; and
forming a convex shell over said seed pillar.

2. The method of claim 1, wherein the creating the seed pillar comprises:
applying a first material over said first substrate;
forming a hole in said first material layer; and
adding a second material to said hole.

3. The method of claim 1, wherein the forming a convex shell over said seed pillar comprises:
surrounding said seed pillar with a third material;
patterning said third material such that a gap is created around said seed pillar, said patterning of said third material layer leaving a remaining portion of said third material layer on said first substrate separated from the seed pillar by the gap;
filling said gap and covering said seed pillar with a shell material to form said convex shell.

4. The method of claim 3, further comprising:
forming a fourth material on the substrate prior to applying the first material to the substrate; and
removing at least a portion of the fourth material not covered by the convex shell.

5. The method of claim 3, wherein the forming the convex shell further comprises:
removing said remaining portion of the third material.

6. The method of claim 3, wherein the filling of said gap is further characterized by using electrolytic plating.

7. The method of claim 3, wherein the filling of said gap is further characterized by using electroless plating.

8. The method of claim 3, wherein the forming the seed pillar comprises:
applying a fourth material on the first substrate.

9. The method of claim 8, wherein said first substrate is selected from the group consisting of an organic substrate, a ceramic substrate, and a silicon substrate.

10. The method of claim 8, wherein said fourth material is an electrical interconnect pad.

11. The method of claim 8, wherein said fourth material is selected from a group consisting of copper, tin, tungsten, molybdenum, silver, aluminum, and nickel.

12. The method of claim 8, wherein said first material comprises photoresist.

13. The method of claim 8, wherein said second material is selected from a group consisting of copper, tin, molybdenum, tungsten, silver, aluminum, and nickel.

14. The method of claim 8, wherein said fourth material is a seed layer.

15. The method of claim 8, wherein the second material, fourth material, and shell material comprise copper.

16. A method for forming a convex solder interconnect pad comprising:
providing a substrate;
forming a seed layer on the substrate;
forming a pillar on the seed layer;
forming a convex conductive shell surrounding the pillar.

17. The method of claim 16 wherein the forming the pillar comprises:
applying a first resist material layer over said seed layer;
forming a hole in said first resist material layer;
adding a seed pillar material to said hole, and
removing said first resist material layer.

18. The method of claim 17, wherein the first resist material layer is photoimageable.

19. The method of claim 17, wherein the first resist material layer is laser definable.

20. The method of claim 17 wherein the forming the convex conductive shell comprises:
surrounding said pillar with a second resist material layer;
removing said second resist material layer around said pillar such that a portion of said seed layer surrounding said pillar is exposed and a top and side portion of said pillar is exposed, whereby there is a remaining portion of the second resist material layer, and
forming a convex conductive shell covering the top and side portions of said pillar.

21. The method of claim 20, further comprising removing the remaining portion of said second resist material layer.

22. The method of claim 20, wherein the second resist material layer is photoimageable.

23. The method of claim 20, wherein the shell comprises a material selected from a group consisting of copper, tin, molybdenum, tungsten, silver, aluminum, and nickel.

24. The method of claim 20, wherein the first resist material is laser definable.

25. The method of claim 16, wherein said first substrate is a non-conductive material.

26. The method of claim 25, wherein said non-conductive material is selected from a group consisting of ceramic, epoxy or polyimide.

27. A method of making a conductive convex pad, comprising:
providing a substrate;
forming a seed layer;
forming a pillar on the seed layer;
surrounding and spacing from the pillar a patterned photoresist layer to leave an exposed portion of the seed layer surrounding the pillar; and
plating the pillar and the exposed portion of the seed layer to form the conductive convex pad.

28. The method of claim 27, wherein the seed layer, the pillar, and the conductive convex pad comprise copper.

29. The method of claim 27, wherein the conductive convex pad comprises an interconnect pad on an integrated circuit.

30. The method of claim 27, wherein the conductive convex pad comprises an interconnect pad on a package circuit or PCB.

31. The method of claim 27, wherein the pillar comprises a material selected from a group consisting of copper, tin, molybdenum, tungsten, silver, aluminum, and nickel.

32. The method of claim 27, wherein the pillar is non-conductive.
